(19) United States
(12) Patent Application Publication
(10) Pub. No.: US 2002/0026609 A1
(43) Pub. Date: Feb. 28, 2002

(54) Semiconductor integrated circuit and test method of built-in analog circuit

(76) Inventors: Brian Worobey, Tokyo (JP); Shuji Murakami, Tokyo (JP)

Correspondence Address: BURNS DOANE SWECKER & MATHIS L L P, POST OFFICE BOX 1404, ALEXANDRIA, VA, 22313-1404, US

(21) Appl. No.: 09/779,617

(22) Filed: Feb. 9, 2001

(30) Foreign Application Priority Data
Aug. 25, 2000 (JP) 2000-256043

(51) Int. Cl. G01R 31/28

(52) U.S. Cl. 714/724

(57) ABSTRACT

Conventional semiconductor integrated circuits have a problem that a test of an analog circuit requires considerable labor and cost. However, an address decoder for decoding an address input from the outside and generating an address signal, a storing unit for storing data for setting a parameter input from the outside in a location indicated by the address signal, and a selector for selecting data stored in the storing means instead of a signal value on a control bus at the time of testing an analog circuit are provided in a semiconductor integrated circuit, thereby allowing reductions in labor and costs.

### BACKGROUND OF THE INVENTION

1. Field of the Invention

The present invention relates to a semiconductor integrated circuit and a test method of a built-in analog circuit where parameters of the analog circuit can be set from the outside at the time of testing the analog circuit.

2. Description of Related Art

In a semiconductor integrated circuit where an analog circuit and a digital circuit coexist in a chip, the performance of the semiconductor integrated circuit may be greatly influenced by changes in parameters such as gain, a delay time and a reference voltage in various circuits such as an amplifier, a delay element and a reference voltage generating circuit included in the analog circuit.

For example, in the case of an amplifier, a reference voltage applied to its current source should have a certain value to ensure the generation of a proper gain. Further, in the case of an analog circuit including a delay element, the delay element should be controlled to give a certain delay to an input signal.

Even if an analog circuit built in a semiconductor integrated circuit includes any type of circuit, it is possible to predict an optimum parameter and physically lay out the analog circuit to obtain the predicted parameter. Further, it is possible to physically modify the layout of the analog circuit by FIB (Focused Ion Beam) correction or laser cutting after its manufacture. For example, the layout of a reference voltage generating circuit can be modified by FIB correction or laser cutting to change the magnitude of a reference voltage. However, when many changes are needed, such a layout modification requires considerable time and cost.

A test is conducted to evaluate whether or not an analog circuit built in a semiconductor integrated circuit exhibits a performance as designed. In the past, when testing an analog circuit, parameters such as a gain, a delay time and a reference voltage should be directly set by applying an analog control signal and the like to a semiconductor integrated circuit from the outside.

FIG. 9 is a block diagram showing a conventional semiconductor integrated circuit provided with a pin to which an analog control signal is applied for a test of an analog circuit built in the semiconductor integrated circuit. In the figure, the reference numeral 1 designates a semiconductor integrated circuit; 11 designates an analog circuit built in the semiconductor integrated circuit 1; 12 designates a digital circuit built in the semiconductor integrated circuit 1; 13 designates an input terminal of the semiconductor integrated circuit 1 for receiving a digital signal from outside a chip of the semiconductor integrated circuit 1; 14 designates an output terminal of the semiconductor integrated circuit 1 for transmitting a digital signal to outside the chip; 15 designates an external terminal for transmitting a control signal and the like to outside the chip and receiving such a signal therefrom; 16 designates a control bus provided in the semiconductor integrated circuit 1 and connected to a control bus such as a I²C bus provided outside the chip through a control bus terminal 17; and 18 designates a control terminal for receiving an analog control signal applied from outside the chip.

Next, the operation of the conventional semiconductor integrated circuit will be described.

For example, in the case of testing an amplifier (not shown) included in the analog circuit 11, an external power supply is connected to the control terminal 18 of the semiconductor integrated circuit 1. A reference voltage of a certain value is applied to a current source of the amplifier through the control terminal 18 to control the current source so that the amplifier has a proper gain. While testing the analog circuit 11, the external terminal 15 is not used, the other part of the semiconductor integrated circuit 1 or the digital circuit 12 is disregarded and the control bus 16 does not operate.

When it is judged by the test that the analog circuit 11 does not exhibit the performance as designed, the layout of the analog circuit 11 may be physically modified.

In the conventional semiconductor integrated circuit thus constructed, at the time of testing the analog circuit built therein, in order to supply an analog control signal of a certain value to the semiconductor integrated circuit, an additional device such as an external power supply should be prepared, resulting in substantial labor and cost. Further, when the analog circuit 11 is judged not to exhibit the performance as designed, it is required to physically modify the layout of the analog circuit 11, resulting in a waste of time and an increase in cost. In order to solve such a problem, it is proposed that a parameter of the analog circuit is set by using a control bus. However, since the control bus operates at a chip level, this results in considerable labor, thereby making the testing of the analog circuit more complex.

### SUMMARY OF THE INVENTION

The present invention is implemented to solve the above problem in the conventional semiconductor integrated circuit. An object of the present invention is to provide a semiconductor integrated circuit and a method of testing an analog circuit built therein where a parameter of the analog circuit can be set by using data input from the outside instead of the value of a signal (signal value) on a control bus during testing of the analog circuit.

According to the present invention, there is provided a semiconductor integrated circuit comprising; a control bus to be used for setting a parameter of an analog circuit; storing means for storing data for setting the parameter input from outside; and selecting means for selecting and outputting the data stored in the storing means instead of a signal value on the control bus at a time of testing the analog circuit, and selecting and outputting the signal value on the control bus at other times, in order to set the parameter.

Here, the semiconductor integrated circuit may further comprise address decoding means for decoding an address input from the outside and generating an address signal; and the storing means may store data in a location indicated by the address signal from the address decoding means.

When a signal value on the control bus takes a certain value, the selection means may select data stored in the storing means instead of the signal value on the control bus.

When a selection signal input from the outside has a certain value, the selection means may select data stored in the storing means instead of a signal value on the control bus.

The semiconductor integrated circuit may further comprise; selection signal generating means for generating a digital selection signal based on the data stored in the storing means or the signal value on the control bus selected by the selection means; and reference voltage generating means for generating a reference voltage having a value corresponding to the digital selection signal.

The semiconductor integrated circuit may further comprise; selection signal generating means for generating a digital selection signal based on the data stored in the storing means or the signal value on the control bus selected by the selection means; and delay means for giving a delay time having a value corresponding to the digital selection signal to an input signal.

The semiconductor integrated circuit may further comprise; selection signal generating means for generating a digital selection signal based on the data stored in the storing means or the signal value on the control bus selected by the selection means; and driving means having a drivability corresponding to the digital selection signal.

The control bus may be a I²C bus.

According to the present invention, there is provided a method of testing an analog circuit built in a semiconductor integrated circuit provided with a control bus to be used for setting a parameter of the analog circuit, comprising the step of setting the parameter by using data input from outside the semiconductor integrated circuit instead of a signal value on the control bus at a time of testing the analog circuit, and by using the signal value on the control bus at other times.

Here, when a signal value on the control bus takes a certain value, the parameter may be set by using data input from outside the semiconductor integrated circuit instead of the signal value on the control bus.

When a selection signal input from outside the semiconductor integrated circuit has a certain value, the parameter may be set-by using data input from outside the semiconductor integrated circuit instead of a signal value on the control bus.

As stated above, according to the present invention, a semiconductor integrated circuit is constructed so as to comprise; storing means for storing data for setting a parameter input from outside; and selecting means for selecting and outputting the data stored in the storing means instead of a signal value on a control bus at a time of testing an analog circuit in order to set the parameter. Thus, at the time of testing the analog circuit, not only an additional pin but also an additional device such as an external power supply for setting a parameter is not required, resulting in reductions in the time and the costs required for the test.

According to the present invention, the semiconductor integrated circuit is constructed so as to further comprise address decoding means for decoding an address input from the outside and generating an address signal; and the storing means stores data in a location indicated by the address signal from the address decoding means. Thus, a plurality of parameters can be simultaneously set at the time of testing an analog circuit.

According to the present invention, the semiconductor integrated circuit is constructed such that when a signal value on the control bus is a certain value, the selection means selects data stored in the storing means instead of the signal value on the control bus. Thus, a test of an analog circuit can be triggered by using the control bus.

According to the present invention, the semiconductor integrated circuit is constructed such that when a selection signal input from the outside has a certain value, the selection means selects data stored in the storing means instead of a signal value on the control bus. Thus, the application of a selection signal from the outside allows easy trigger of a test of an analog circuit by using data.

According to the present invention, the semiconductor integrated circuit is constructed so as to further comprise; selection signal generating means for generating a digital selection signal based on the data stored in the storing means or the signal value on the control bus selected by the selection means; and reference voltage generating means for generating a reference voltage having a value corresponding to the digital selection signal. Thus, at the time of testing an analog circuit, not only an additional pin but also an additional device such as an external power supply for setting a reference voltage is not required, resulting in reductions in the time and the costs required for the test.

According to the present invention, the semiconductor integrated circuit is constructed so as to further comprise; selection signal generating means for generating a digital selection signal based on the data stored in the storing means or the signal value on the control bus selected by the selection means; and delay means for giving a delay time having a value corresponding to the digital selection signal to an input signal. Thus, at the time of testing an analog circuit, an additional pin and device such as an external power supply for setting a delay time are not required, resulting in reductions in the time and the costs required for the test.

According to the present invention, the semiconductor integrated circuit is constructed so as to further comprise; selection signal generating means for generating a digital selection signal based on the data stored in the storing means or the signal value on the control bus selected by the selection means; and driving means having a drivability corresponding to the digital selection signal. Thus, an additional pin and device for setting a drivability at the time of testing an analog circuit are not required, resulting in reductions in the time and the costs required for the test.

### BRIEF DESCRIPTION OF THE DRAWINGS

FIG. 1 is a block diagram showing the construction of a semiconductor integrated circuit according to the embodiment 1 of the present invention.

FIG. 2 is a block diagram showing the construction of the control circuit as shown in FIG. 1 according to the embodiment 1 of the present invention.

FIG. 3 is a block diagram showing the construction of an example of a selector included in the control circuit as shown in FIG. 2 according to the embodiment 1 of the present invention.

FIG. 4 is a block diagram showing the detailed construction of the example of the selector as shown in FIG. 3.

FIG. 5 is a block diagram showing the construction of a control circuit included in a semiconductor integrated circuit according to the embodiment 2 of the present invention.

FIG. 6 is a block diagram showing the construction of an analog circuit included in a semiconductor integrated circuit according to the embodiment 3 of the present invention.

FIG. 7 is a block diagram showing the construction of an analog circuit included in a semiconductor integrated circuit according to the embodiment 4 of the present invention.

FIG. 8 is a block diagram showing the construction of an analog circuit included in a semiconductor integrated circuit according to the embodiment 5 of the present invention.

FIG. 9 is a block diagram showing the construction of a conventional semiconductor integrated circuit.

### DETAILED DESCRIPTION OF THE PREFERRED EMBODIMENTS

An embodiment of the invention will be described.

Embodiment 1

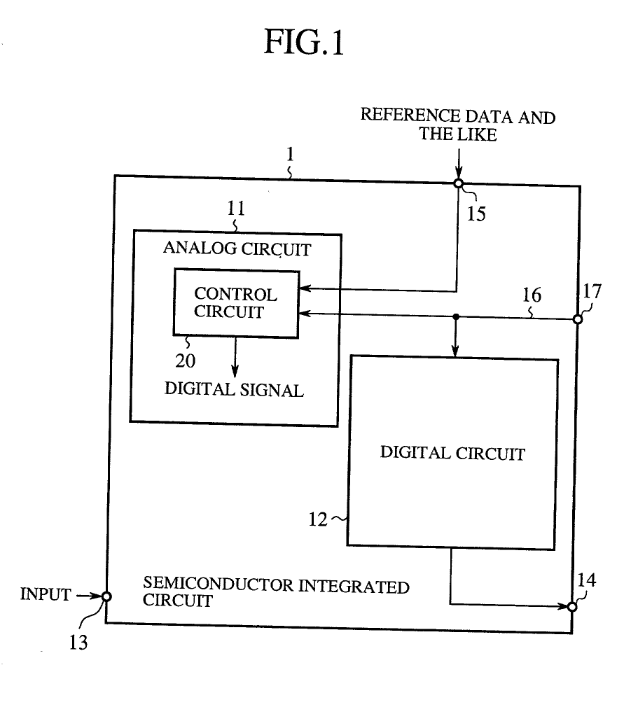

FIG. 1 is a block diagram showing the construction of a semiconductor integrated circuit according to the embodiment 1 of the present invention. In the figure, the reference numeral 1 designates a semiconductor integrated circuit; 11 designates an analog circuit built in the semiconductor integrated circuit 1; 12 designates a digital circuit built in the semiconductor integrated circuit 1; 13 designates an input terminal of the semiconductor integrated circuit 1 for receiving a digital signal applied from the outside; 14 designates an output terminal of the semiconductor integrated circuit 1 for transmitting a digital signal to the outside; 15 designates an external terminal for transmitting a control signal and the like to the outside and receiving such a signal therefrom; 16 designates a control bus provided in the semiconductor integrated circuit 1 and connected to a control bus provided outside a chip of the semiconductor integrated circuit 1 through a control bus terminal 17; and 20 designates a control circuit provided in the analog circuit 11. An example of the control bus 16 is a I²C bus, but it is not limited thereto. A control signal is input from the outside through the control bus 16 to control the digital circuit 12, the analog circuit 11 and the like. The external terminal 15 is composed of a plurality of pins including chip I/O pins provided in the chip of the semiconductor integrated circuit 1 which have not been conventionally used to test the analog circuit 11.

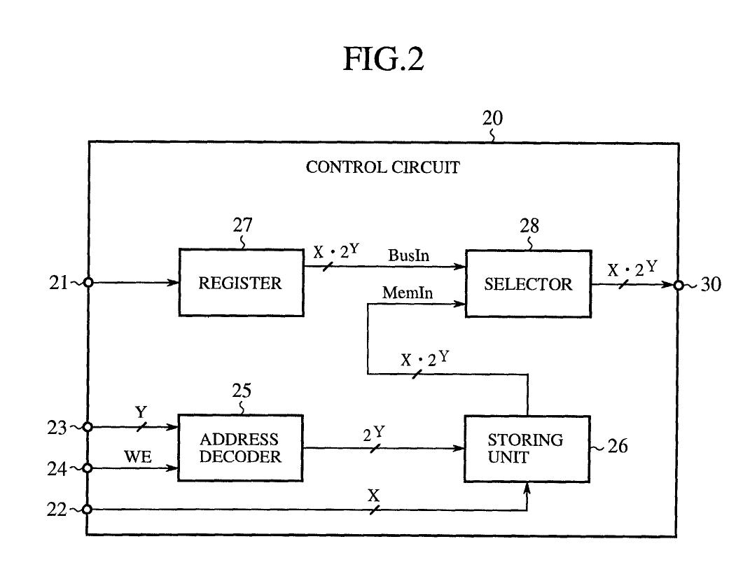

FIG. 2 is a block diagram showing the construction of the control circuit 2. In the figure, the reference numeral 21 designates a control bus terminal connected to the control bus 16; 22 designates a data terminal connected to the external terminal 15 of the semiconductor integrated circuit 1 for receiving X-bit data from the outside; 23 designates an address terminal connected to the external terminal 15 of the semiconductor integrated circuit 1 for receiving a Y-bit address from the outside; 24 designates a write enable (WE) terminal connected to the external terminal 15 of the semiconductor integrated circuit 1 for receiving a WE signal from the outside; 25 designates an address decoder (address decoding means) for generating an address signal indicating a storage location of X-bit data applied to the data terminal 22 from a Y-bit address applied through the address terminal 23 in response to a WE signal applied through the WE terminal 24; 26 designates a storing unit (storing means) for storing X-bit data applied to the data terminal 22 in a location indicated by an address signal from the address decoder 25, and outputting all stored X-bit data (the maximum number of X-bit data is 2^{Y}) as a MemIn; 27 designates a register for storing a signal value on the control bus 16 input through the control bus terminal 21, and outputting the stored data as a BusIn; and 28 designates a selector (selecting means) for selecting a BusIn supplied from the register 27 in the case where the BusIn has a certain value and selecting a MemIn in the other cases, and outputting it through an output terminal 30.

Next, the operation of the semiconductor integrated circuit will be described.

The analog circuit 11 built in the semiconductor integrated circuit 1 can be tested without the use of the control bus 16. In this case, the external terminal 15 is used to input X-bit data, a WE signal and a Y-bit address to the control circuit 20.

For example, in the case where the control bus 16 is a I²C bus, 8-bit data is input to the storing unit 6 through the data terminal 22, while 2-bit data is input to the address decoder 25 through the address terminal 23. In this case, the storing unit 26 is composed of four 1-bite memory blocks. The required capacity of the storing unit 26 depends on the number of parameters of the analog circuit 11 to be set and the number of changes in each parameter. In the above example, the control circuit 20 can output six sets of 5-bit digital reference signals which can have different values of 32 levels to simultaneously set 6 parameters of the analog circuit 11 such as a reference voltage, a delay time and drivability. Further, the control circuit 2 can generate a digital reference signal having a different number of levels for every parameter. Hereinafter, it is assumed that X is 8 and Y is 2.

The address decoder 25 decodes a 2-bit address applied through the address terminal 23 to output a 4-bit address signal to the storing unit 26 in response to a WE signal applied through the WE terminal 24. The storing unit 26 stores 8-bit data applied to the data terminal 22 in a location indicated by the address signal. At this time, four 8-bit data are stored in the storing unit 26 to set all parameters of the analog circuit 11. For example, in the case where it is required to set 6 parameters capable of having different values of 32 levels such as a reference voltage, a delay time and drivability, four 8-bit data are sequentially stored while sequentially changing an address. The storing unit 26 outputs all 32-bit data stored therein as a MemIn to the selector 28.

On the other hand, the register 27 can store a signal value on the control bus 16 through the control bus terminal 21. When the control bus 16 is a I²C bus, for example, data of 8 bits×4=32 bits are serially input to the register 27. The register 27 outputs the 32-bit data to the selector 28 as a BusIn. The selector 28 selects a MemIn in the case where a BusIn has a certain value or a BusIn in the other cases to output it to the outside through the output terminal 30. For example, the selected signal is then used to simultaneously set a plurality of certain parameters of the analog circuit 11.

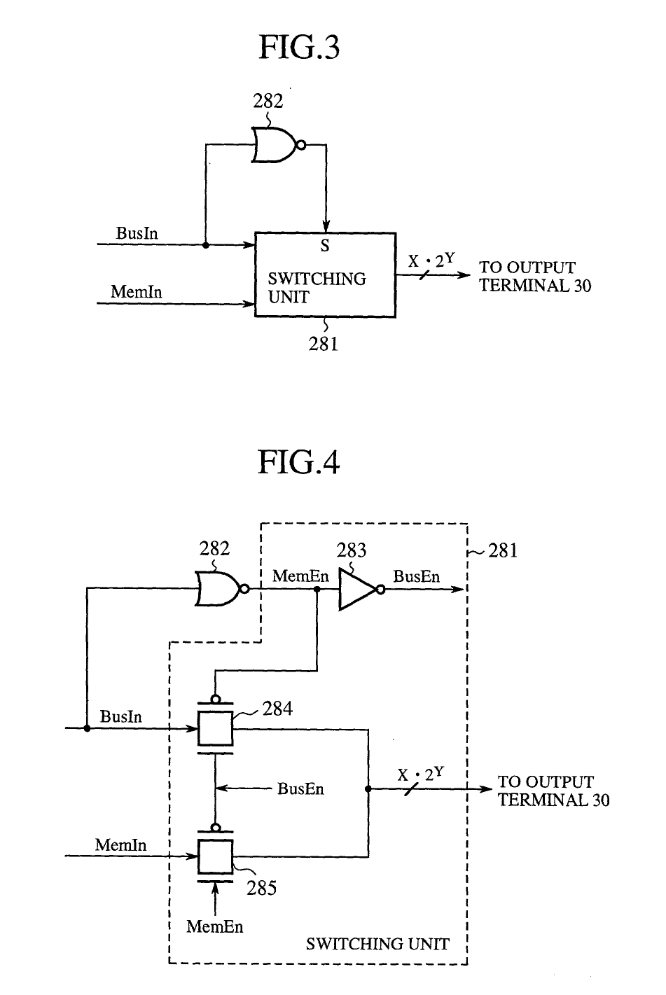

When a BusIn has a certain value, all data stored in the storing unit 26 through the output terminal 15 and data terminal 22 may be used to simultaneously set a plurality of certain parameters of the analog circuit 11. When a BusIn has a value other than the certain value, data input through the control bus 16 may be similarly used. FIG. 3 is a block diagram showing the construction of the selector 28 with a certain value of 0x00000000. In the figure, the reference numeral 281 designates a switching unit which selects a MemIn in the case where a value input to a selection terminal S is “1” or a BusIn in the other cases; and the reference numeral 282 designates a NOR gate which performs an exclusive OR operation of a plurality of inputs. When all bits of a BusIn are zero or the I²C bus has a value of 0x00000000, the NOR gate 282 outputs “1”. As a result, the switching unit 281 selects and outputs a MemIn. In this case, as stated above, all data stored in the storing unit 26 is used to set a plurality of certain parameters. On the contrary, when at least one bit of a BusIn is 1 or the I²C bus has a value other than 0x00000000, the NOR gate 282 outputs “0”. As a result, the switching unit 281 selects and outputs the BusIn. In this case, as stated above, data input through the I²C bus is used to set the certain parameters.

FIG. 4 is a block diagram showing a detailed example of the selector 28 as shown in FIG. 3. In the figure, the reference numeral 283 designates an inverter which inverts an output MemEn from the NOR gate 283 to supply the inverted output as a BusEn and the reference numerals 284 and 285 designate transfer gates. The inverter 283 and the transfer gates 284, 285 constitute the switching unit 281 as shown in FIG. 3. When all bits of a BusIn are zero, or a MemEn is “1” and a BusEn is “0”; the transfer gate 284 intercepts an input BusIn and the transfer gate 285 lets an input MemIn pass. On the contrary, when at least one bit of a BusIn is “1”, or a MemEn is “0” and a BusEn is “1”; the transfer gate 284 lets an input BusIn pass and the transfer gate 285 intercepts an input MemIn.

Further, by changing the NOR gate 282 as shown in FIG. 3, any value other than 0x00000000 can be used as a value of the I²C bus which triggers the use of data stored in the storing unit 26. Such a change is allowed in cases of using any kind of control bus. A certain value of the control bus 16 for triggering the use of data stored in the storing unit 26 may be any value.

As stated above, according to the embodiment 1, when a signal value on the control bus 16 is a certain value, parameters of the analog circuit can be set by using data input through the external terminal (MemIn). Thus, at the time of testing the analog circuit, not only an additional pin but also an additional device such as an external power supply for setting parameters is not required, resulting in reductions in the time and the costs required for the test. Further, the control bus 16 can be used to easily trigger a test of an analog circuit by using data.

Embodiment 2

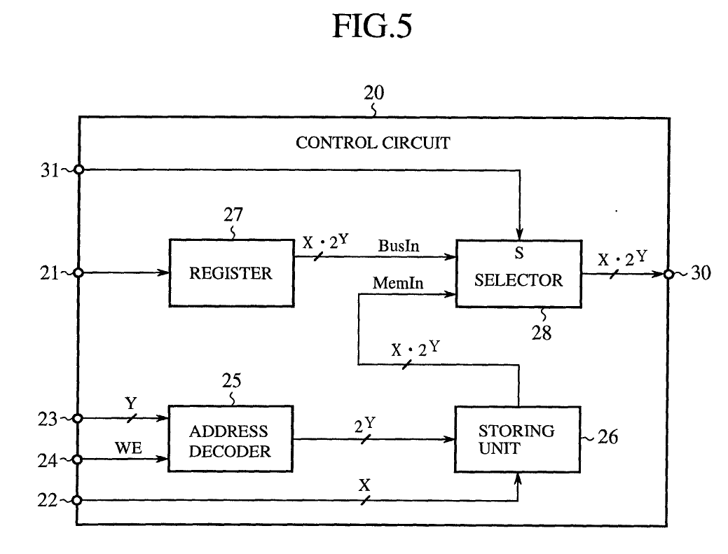

FIG. 5 is a block diagram showing the construction of a control circuit included in a semiconductor integrated circuit according to the embodiment 2 of the present invention. A semiconductor integrated circuit according to the embodiment 2 is of the same construction as that of the semiconductor integrated circuit according to the embodiment 1. In FIG. 5, like reference numerals of FIG. 2 designate like or corresponding constituent elements of the control circuit according to the embodiment 1 and detailed explanation therefor is omitted. The reference numeral 31 designates a selection terminal connected to an external terminal 15 of a semiconductor integrated circuit 1 for receiving a selection signal of selecting a BusIn or a MemIn from the outside. As stated previously in the embodiment 1, the external terminal 15 is composed of a plurality of pins including chip I/O pins provided in a chip of the semiconductor integrated circuit 1 which have not been conventionally used to test an analog circuit 11.

Next, the operation of the control circuit will be described.

The operation of the control circuit 20 according to the embodiment 2 is basically the same as that of the embodiment 1 and only different operation will be described.

When a selection signal received from the selection terminal 31 has a certain value, e.g., “1”, the selector 28 selects a MemIn, while when a selection signal has a value of “0”, it selects a BusIn. The selector 28 then outputs it to the outside through the output terminal 30. On the other words, in order to simultaneously set a plurality of parameters of an analog circuit 11, all data stored in a storing unit 26 through the external terminal 15 and data terminal 22 is used, when a selection signal has a certain value, whereas data input through a control bus 16 is used when a selection signal has a value other than the certain value.

As stated above, according to the embodiment 2, when a selection signal applied from the outside has the certain value, parameters of the analog circuit can be set by using data input through the external terminal (MemIn). Thus, at the time of testing an analog circuit, not only an additional pin but also an additional device such as an external power supply is unnecessary, thereby reducing the time and the costs required for the test. Further, the application of a selection signal from the outside allows data to be used to facilitate the trigger of a test of an analog circuit.

Embodiment 3

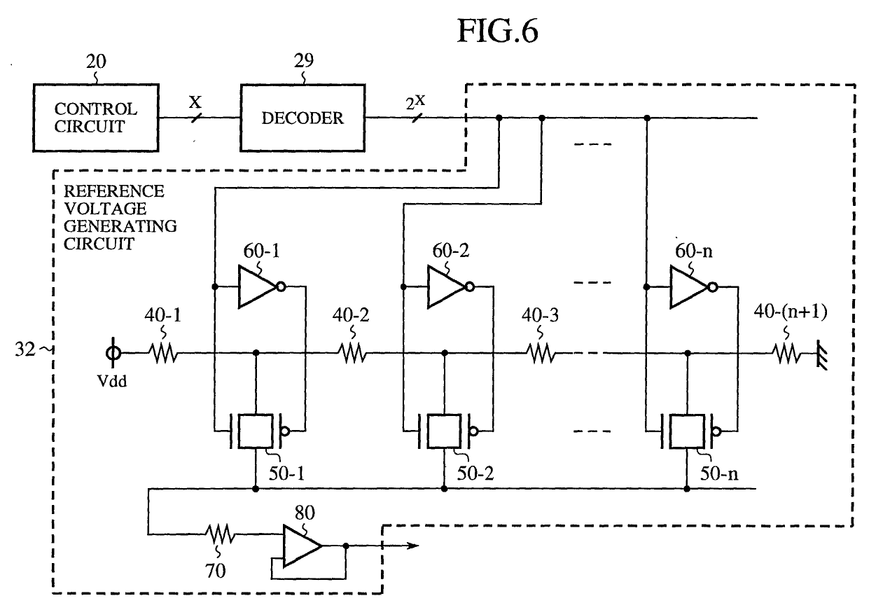

FIG. 6 is a block diagram showing the construction of an analog circuit included in a semiconductor integrated circuit according to the embodiment 3 of the present invention. The semiconductor integrated circuit of the embodiment 3 is of the same construction as that of semiconductor integrated circuit of the embodiment 1 as shown in FIG. 1. In FIG. 6, like reference numerals of FIG. 1 designate like or corresponding constituent elements of the analog circuit according to the embodiment 1 and detailed explanation therefor is omitted. In FIG. 6, the reference numeral 29 designates a decoder (selection signal generating means) which decodes a digital signal of X-bit data from a control circuit 20 and outputs a 2X-bit digital reference signal where a bit corresponding to a value of the digital signal is “1”; 32 designates a reference voltage generating circuit (reference voltage generating means); 40-1 to 40(n+1) designate a series of resistors connected between a power supply Vdd and ground in series; 50-1 to 50-n designate transfer gates; and 60-1 to 60-n designate inverters with the inputs thereof connected to the output of the control circuit 20 and control terminals of corresponding transfer gates, and the outputs thereof connected to inversion control terminals of the transfer gates. As shown in FIG. 6, an end of a transfer gate 50-i is connected to a connecting point between a resistor 40-i and a resistor 40-(i+1) wherein i=1 to n. The other ends of all the transfer gates 50-1 to 50-n are connected to each other and then to a buffer 80 through a resister 70.

Next, the operation of the analog circuit will be described.

The operation of a control circuit 20 according to the embodiment 3 is basically the same as that of the embodiment 1 and explanation therefor is omitted. Further, for simplicity, the following description is based on the assumption that an output of the control circuit 20 is a 5-bit digital signal, an output of the decoder 29 is then a 32-bit (=2⁵) digital reference signal, n=32 and Vdd=3.3 V.

In an example where the control circuit 20 according to the embodiment 1 is combined with the reference voltage generating circuit 32 as shown in FIG. 6, if a series of the resisters 40-1 to 40-33 has the same resistance, the reference voltage generating circuit 32 can generate reference voltages of 0.1V to 3.2V in 0.1V increments through the buffer 80.

The decoder 29 decodes a 5-bit digital signal output from the control circuit 20 and then outputs a 32-bit digital reference signal to the reference voltage generating circuit 32, thereby setting a reference voltage generated by the reference voltage generating circuit 32 to a certain value. On the other words, the decoder 29 decodes a 5-bit digital signal from the control circuit 20 to generate a 32-bit (32=2⁵) digital reference signal where a bit corresponding to the value of the digital signal is “1”. Thus, according to the value of the 32-bit digital reference signal applied by the decoder 29, “1” is input to only one of the inputs of the inverters 60-1 to 60-32 and the control terminal of the corresponding transfer gate 50-i (i=1 to 32). As a result, only the transfer gate 50-i is set to “ON” and the connecting point between the corresponding resistors 40-i and 40-(i+1) is connected to the buffer 80 through the transfer gate 50-i and the resister 70. The reference voltage generating circuit 32 generates reference voltages of 0.1V to 3.2V in 0.1V increments based on 32-bit digital reference signals applied from the decoder 29.

The output of the buffer 80 is preferably connected to an operating amplifier so that the reference voltage generating circuit 32 is not influenced by any outside circuit. This prevents a current from flowing to an analog circuit requiring a reference voltage from the reference voltage generating circuit 32. As a result, since driving can be mainly conducted by individual operational amplifiers, the number of analog circuits driven by the reference voltage generating circuit 32 is not limited.

As stated above, according to the embodiment 3, the value of a reference voltage generated by the reference voltage generating circuit 32 can be set by using data input through the external terminal (MemIn). Thus, at the time of testing an analog circuit, not only an additional pin but also an additional device such as an external power supply for setting a reference voltage is not required, resulting in reductions in the time and the costs required for the test.

Embodiment 4

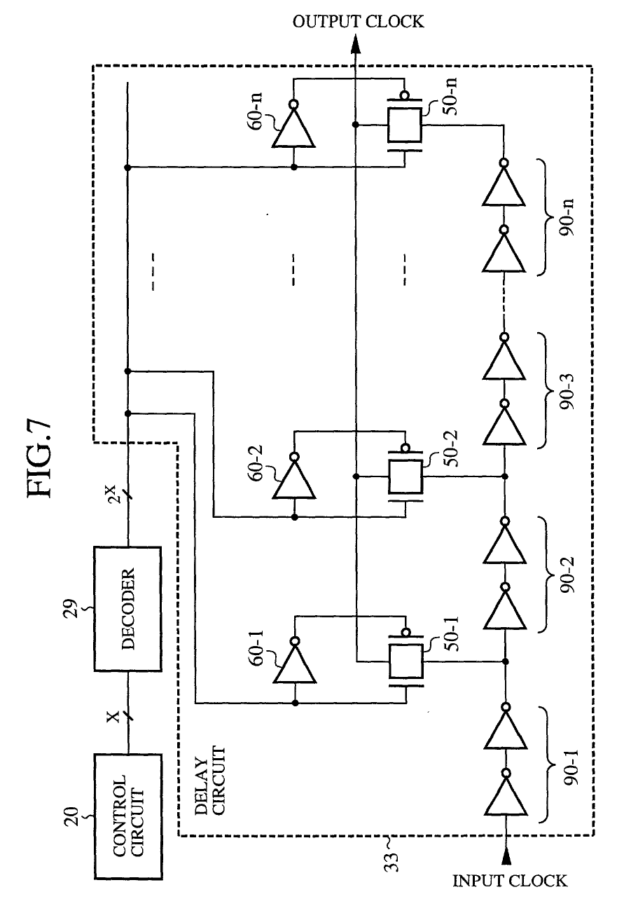

FIG. 7 is a block diagram showing the construction of an analog circuit included in a semiconductor integrated circuit according to the embodiment 4 of the present invention. The semiconductor integrated circuit of the embodiment 4 is of the same construction as that of semiconductor integrated circuit of the embodiment 1 as shown in FIG. 1. In FIG. 7, like reference numerals of FIGS. 1 to 6 designate like or corresponding constituent elements of the analog circuits according to the embodiments 1 and 3, and detailed explanation therefor is omitted. In FIG. 7, the reference numeral 33 designates a delay circuit (delay means) and the reference numerals 90-1 to 90-n designate pairs of inverters each composed of two inverters connected in series. As shown in FIG. 7, pairs of inverters 90-1 to 90-n are connected in series and an end of a transfer gate 50-i is connected to a connecting point between pairs of inverters 90-i and 90-(i+1) (i=1 to n). The other ends of the transfer gates 50-1 to 50-n are connected to each other and delayed clocks are output through these connecting points.

Next, the operation of the analog circuit will be described.

The operation of a control circuit 20 and a decoder 29 according to the embodiment 4 is basically the same as those of the embodiments 1 and 3 and explanation therefor is omitted. Further, for simplicity, the following description is based on the assumption that an output of the control circuit 20 is a 5-bit digital signal, an output of the decoder 29 is then a 32-bit (=2⁵) digital reference signal, and n=32.

As shown in FIG. 7, in an example where the control circuit 20 of the embodiment 1 is combined with the delay circuit 33, if a series of pairs of inverters 90-1 to 90-32 provide the same delay time to an input signal, an input clock is output with a delay obtained by multiplying the number of pairs of inverters which the clock has passed through by the delay time.

Specifically, “1” is input to only one of the inputs of inverters 60-1 to 60-32 and the control terminal of the corresponding transfer gate 50-i (i=1 to 32) according to the value of a 32-bit digital reference signal input from the decoder 29. As a result, only the transfer gate 50-i is set to “ON” and the connecting point between the corresponding pair of inverters 90-i and 90-(i+1) is connected to the output through the transfer gate 50-i. The delay circuit 33 gives a delay time based on the digital reference signal to an input clock by letting the clock pass through pairs of inverters corresponding to the transfer gate 50-i set to “ON”.

As stated above, according to the embodiment 4, a delay time can be set by using data input through an external terminal (MemIn). Thus, an additional pin and device for setting a delay time at the time of testing an analog circuit are not required, resulting in reductions in the time and the costs required for the test.

Embodiment 5

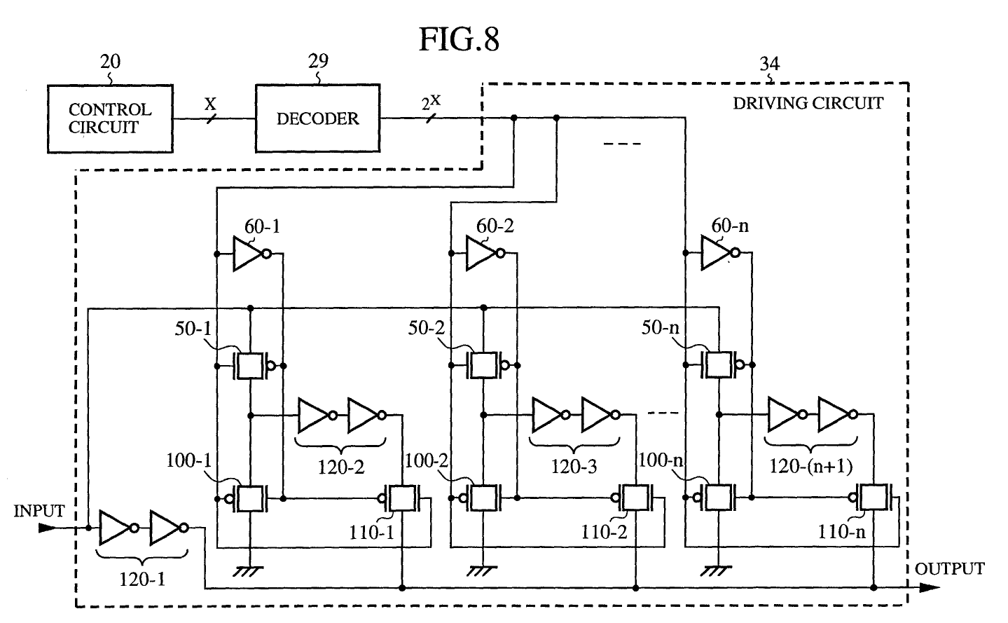

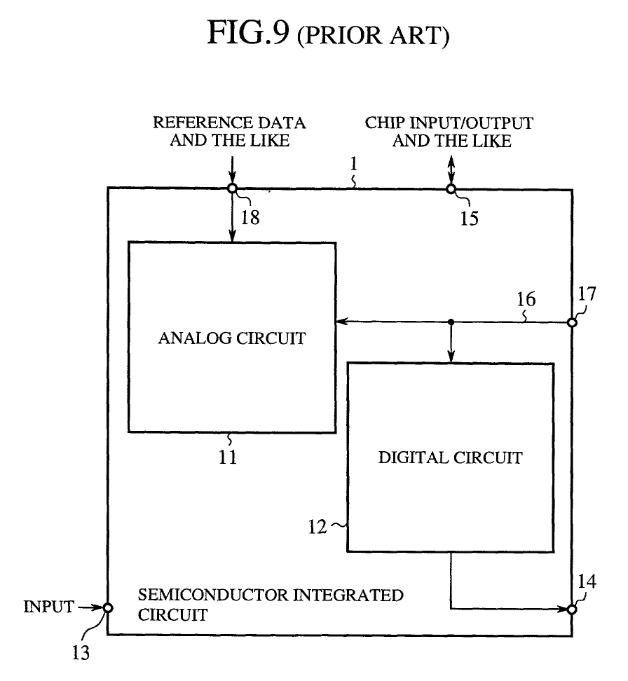

FIG. 8 is a block diagram showing the construction of an analog circuit included in a semiconductor integrated circuit according to the embodiment 5 of the present invention. The semiconductor integrated circuit of the embodiment 5 is of the same construction as that of semiconductor integrated circuit of the embodiment 1 as shown in FIG. 1. In FIG. 8, like reference numerals of FIGS. 1 to 6 designate like or corresponding constituent elements of the analog circuits according to the embodiments 1 and 3, and detailed explanation therefor is omitted. In FIG. 8, the reference numeral 34 designates a driving circuit (driving means); 100-1 to 100-n and 110-1 to 110-n designate transfer gates; and 120-1 to 120-(n+1) designate pairs of inverters each composed of two inverters connected in series. An inverter of a pair 120-2 to 120-(n+1) at the output side has a different drivability from those of the others. For example, the drivability of the pairs of inverters 120-2 to 120-(n+1) increases in this sequence.

As shown in FIG. 8, a control terminal of a transfer gate 50-i (i=1 to n) and an inversion control terminal of a transfer gate 100-i are connected to the input of inverter 60-i. An inversion control terminal of a transfer gate 50-i (i=1 to n) and a control terminal of a transfer gate 100-i are connected to the output of inverter 60-i. An end of each transfer gate 50-i is connected to the input of the driving circuit 34 and an input signal is applied to the end of each transfer gate 50-i. The other end of each transfer gate 50-i is connected to an end of the corresponding transfer gate 100-i and the input of a pair of inverters 120-(i+1). The other end of each transfer gate 100-i is connected to ground.

Further, the output of a pair of inverters 120-(i+1) is connected to an end of a transfer gate 110-i. An inversion control terminal of the transfer gate 110-i is connected to the output of an inverter 60-i, while a control terminal thereof is connected to the input of the inverter 60-i. The other ends of all the transfer gates 110-1 to 110-n are connected to each other, and these connecting points are then connected to the output of a pair of inverters 120-1 and the output of the driving circuit 34.

Next, the operation of the analog circuit will be described.

The operation of a control circuit 20 and a decoder 29 according to the embodiment 5 is basically the same as those of the embodiments 1 and 3 and explanation therefor is omitted. Further, for simplicity, the following description is based on the assumption that an output of the control circuit 20 is a 5-bit digital signal, an output of the decoder 29 is then a 32-bit (=2⁵) digital reference signal, and n=32.

As shown in FIG. 8, in an example where the control circuit 20 of the embodiment 1 is combined with the driving circuit 34, a selected pair of inverters 120-(i+1) (i=1 to n) is connected to the first pair of inverters 120-1 in parallel.

Specifically, “1” is input to only one of the inputs of inverters 60-1 to 60-32 and the control terminals of the corresponding transfer gates 50-i and 110-i according to the value of a 32-bit digital reference signal input from the decoder 29. As a result, only the transfer gates 50-i and 110-i are set to “ON” and the corresponding pair of inverters 120-(i+l) is then connected to the first pair of inverters 120-1 between the input and the output of the driving circuit 34 in parallel. Consequently, the output current or drivability of the driving circuit 34 can be increased by the pair of inverters 120-(i+l) connected in parallel.

As stated above, according to the embodiment 5, the drivability of the driving circuit 34 can be set by using data input through an external terminal (MemIn). Thus, an additional pin and device for setting drivability at the time of testing an analog circuit are not required, resulting in reductions in the time and the costs required for the test.

What is claimed is:

1. A semiconductor integrated circuit comprising;
a control bus to be used for setting a parameter of an analog circuit;
storing means for storing data for setting the parameter input from outside; and
selecting means for selecting and outputting the data stored in the storing means instead of a signal value on the control bus at a time of testing the analog circuit, and selecting and outputting the signal value on the control bus at other times, in order to set the parameter.

2. A semiconductor integrated circuit as defined in claim 1, further comprising address decoding means for decoding an address input from the outside and generating an address signal; the storing means storing data in a location indicated by the address signal from the address decoding means.

3. A semiconductor integrated circuit as defined in claim 1, wherein when a signal value on the control bus is a certain value, the selection means selects data stored in the storing means instead of the signal value on the control bus.

4. A semiconductor integrated circuit as defined in claim 1, wherein when a selection signal input from the outside has a certain value, the selection means selects data stored in the storing means instead of a signal value on the control bus.

5. A semiconductor integrated circuit as defined in claim 1, further comprising;
selection signal generating means for generating a digital selection signal based on the data stored in the storing means or the signal value on the control bus selected by the selection means; and
reference voltage generating means for generating a reference voltage having a value corresponding to the digital selection signal.

6. A semiconductor integrated circuit as defined in claim 2, further comprising;
selection signal generating means for generating a digital selection signal based on the data stored in the storing means or the signal value on the control bus selected by the selection means; and
reference voltage generating means for generating a reference voltage having a value corresponding to the digital selection signal.

7. A semiconductor integrated circuit as defined in claim 3, further comprising;
selection signal generating means for generating a digital selection signal based on the data stored in the storing means or the signal value on the control bus selected by the selection means; and
reference voltage generating means for generating a reference voltage having a value corresponding to the digital selection signal.

8. A semiconductor integrated circuit as defined in claim 4, further comprising;
selection signal generating means for generating a digital selection signal based on the data stored in the storing means or the signal value on the control bus selected by the selection means; and
reference voltage generating means for generating a reference voltage having a value corresponding to the digital selection signal.

9. A semiconductor integrated circuit as defined in claim 1, further comprising;
selection signal generating means for generating a digital selection signal based on the data stored in the storing means or the signal value on the control bus selected by the selection means; and
delay means for giving a delay time having a value corresponding to the digital selection signal to an input signal.

10. A semiconductor integrated circuit as defined in claim 2, further comprising;
selection signal generating means for generating a digital selection signal based on the data stored in the storing means or the signal value on the control bus selected by the selection means; and
delay means for giving a delay time having a value corresponding to the digital selection signal to an input signal.

11. A semiconductor integrated circuit as defined in claim 3, further comprising;
selection signal generating means for generating a digital selection signal based on the data stored in the storing means or the signal value on the control bus selected by the selection means; and
delay means for giving a delay time having a value corresponding to the digital selection signal to an input signal.

12. A semiconductor integrated circuit as defined in claim 4, further comprising;
selection signal generating means for generating a digital selection signal based on the data stored in the storing means or the signal value on the control bus selected by the selection means; and
delay means for giving a delay time having a value corresponding to the digital selection signal to an input signal.

13. A semiconductor integrated circuit as defined in claim 1, further comprising;
selection signal generating means for generating a digital selection signal based on the data stored in the storing means or the signal value on the control bus selected by the selection means; and
driving means having a drivability corresponding to the digital selection signal.

14. A semiconductor integrated circuit as defined in claim 2, further comprising;
selection signal generating means for generating a digital selection signal based on the data stored in the storing means or the signal value on the control bus selected by the selection means; and
driving means having a drivability corresponding to the digital selection signal.

15. A semiconductor integrated circuit as defined in claim 3, further comprising;
selection signal generating means for generating a digital selection signal based on the data stored in the storing means or the signal value on the control bus selected by the selection means; and
driving means having a drivability corresponding to the digital selection signal.

16. A semiconductor integrated circuit as defined in claim 4, further comprising;
selection signal generating means for generating a digital selection signal based on the data stored in the storing means or the signal value on the control bus selected by the selection means; and
driving means having a drivability corresponding to the digital selection signal.

17. A semiconductor integrated circuit as defined in claim 1, wherein the control bus is a I²C bus.

18. A method of testing an analog circuit built in a semiconductor integrated circuit provided with a control bus to be used for setting a parameter of the analog circuit, comprising the step of;
setting the parameter by using data input from outside the semiconductor integrated circuit instead of a signal value on the control bus at a time of testing the analog circuit, and by using the signal value on the control bus at other times.

19. A method as defined in claim 18, wherein when a signal value on the control bus is a certain value, the parameter is set by using data input from outside the semiconductor integrated circuit instead of the signal value on the control bus.

20. A method as defined in claim 18, wherein when a selection signal input from outside the semiconductor integrated circuit has a certain value, the parameter is set by using data input from outside the semiconductor integrated circuit instead of a signal value on the control bus.
